(19) United States
(12) Patent Application Publication
(10) Pub. No.: US 2009/0140374 A1
(43) Pub. Date: Jun. 4, 2009

(54) SEMICONDUCTOR DEVICE WITH IMPROVED CONTROL ABILITY OF A GATE AND METHOD FOR MANUFACTURING THE SAME

(76) Inventor: Kang Sik CHOI, Gyeonggi-do (KR)

Correspondence Address: LADAS & PARRY LLP, 224 SOUTH MICHIGAN AVENUE, SUITE 1600, CHICAGO, IL, 60604, US

(21) Appl. No.: 11/968,515

(22) Filed: Jan. 2, 2008

(30) Foreign Application Priority Data
Nov. 30, 2007 (KR) 10-2007-0123777

(51) Int. Cl. H01L 21/762; H01L 29/49

(52) U.S. Cl. 257/506; 438/425; 257/E29.15; 257/E21.546

(57) ABSTRACT

Disclosed is a semiconductor device capable of improving a control ability of a gate and enhancing operation characteristics of the gate. The semiconductor device comprises a semiconductor substrate having a recessed active region. An isolation structure is formed to define the recessed active region in the semiconductor substrate and the isolation structure includes a trench, a side wall insulation layer formed over the surface of the trench, and an insulation layer formed over the side wall insulation layer to fill the trench. A portion of the side wall insulation layer adjoining a gate forming area of the recessed active region is removed to form a moat, and a gate is formed over the semiconductor substrate including the moat.

### CROSS-REFERENCE TO RELATED APPLICATIONS

The present application claims priority to Korean patent application number 10-2007-0123777 filed on Nov. 30, 2007, which is incorporated herein by reference in its entirety.

### BACKGROUND OF THE INVENTION

The present invention relates to a semiconductor device and a method for manufacturing the same, and more particularly to, a semiconductor device which is capable of improving the control ability of a gate and enhancing operation characteristics of the gate.

As a semiconductor device becomes highly integrated, the channel length of a transistor is decreased, and the ion implantation concentration into source and drain areas is increased. As a consequence, a short-channel effect occurs, wherein interference between the source area and the drain area is increased and the control ability of the gate of a transistor is reduced; and thus, the threshold voltage (Vt) of the transistor is lowered sharply. Conventional semiconductors with planar channels have encountered various limitations when trying to overcome problems related to the high level of integration in semiconductor devices. Accordingly, recent studies have been conducted on a semiconductor device having a recess channel that is capable of ensuring an effective channel length.

Hereinafter, a method for manufacturing a semiconductor with a recess channel in accordance with the prior art will be briefly described.

An isolation layer for defining an active region in a semiconductor substrate is formed, and thereafter a recess mask for exposing a gate forming area of the active region is formed over the semiconductor substrate formed with the isolation layer. The exposed portion of the semiconductor substrate is recessed to form a groove, and the recess mask is then removed. A channel ion implantation process for threshold voltage control is carried out on the active region formed with the groove. The resultant semiconductor substrate (into which the channel ion implantation process has been carried out) is cleaned to remove a naturally occurring oxide layer located over the surface of the semiconductor substrate.

A gate insulation layer is formed over the semiconductor substrate including the groove, and then a gate conductive layer and a hard mask layer are sequentially formed over the gate insulation layer to fill the groove. Thereafter, the hard mask layer, the gate conductive layer, and the gate insulation layer are etched, thereby forming a gate in the gate forming area.

In the prior art described above, the gate does not sufficiently surround the recessed portion of the active region, i.e. the channel portion; and therefore, there a disadvantage results in that the control ability of the gate is limited. Also, in the above described prior art, the threshold voltage characteristics of the gate are deteriorated in edges of the recessed portion of the active region, and this deterioration causes a turn-on phenomenon of the channel. It therefore becomes inevitable that the operation characteristics of the gate will lower as the operation current is reduced.

In order to form the gate to surround the recessed portion of the active region, a method of forming a moat at both sides of the recessed portion of the active region has been suggested. The moat is formed by increasing the cleansing time, and thus removing a side wall oxide layer portion at an upper end portion of a side wall of a trench.

In this case, the gate is formed to surround the recessed portion of the active region including the moat, and thus to some extent it is possible to improve the control ability of the gate. However, when the cleansing time is increases a deep moat is formed in the rest portion as well as the gate forming area. Gate material remains in the moat formed in the rest portion, resulting in the generation of a bridge between adjacent conductive patterns. It is therefore impossible to successfully solve the problems occurring in the prior art by simply increasing the cleansing time.

### SUMMARY OF THE INVENTION

Embodiments of the present invention are directed to a semiconductor device capable of improving the control ability of a gate and a method for manufacturing the same.

Also, embodiments of the present invention are directed to a semiconductor device capable of enhancing the operation characteristics of the gate and a method for manufacturing the same.

In one embodiment, a semiconductor device comprises a semiconductor substrate having an isolation region, an active region, and a gate forming area; an isolation structure formed to define the active region, the isolation structure including a trench formed in the isolation region, a side wall insulation layer formed over the surface of the trench, and an insulation layer formed over the side wall insulation layer to fill the trench; wherein the gate forming area in the active region is recessed forming a recessed active region and wherein an upper end portion of the side wall insulation layer adjoining the gate forming area of the recessed active region is removed to form a moat; and a gate formed over the semiconductor substrate including the moat.

Preferably, the side wall insulation layer includes an oxide layer.

Preferably, the isolation structure further includes a linear nitride layer interposed between the side wall insulation layer and the insulation layer.

Preferably, the moat has a depth of less than half of a channel width of the semiconductor device.

The moat has the depth in the range of 20 to 300 Å.

In another embodiment, a method for manufacturing a semiconductor device comprises the steps of etching a semiconductor substrate to form a trench; forming a side wall insulation layer over a surface of the trench; filling the trench with an insulation layer to form an isolation structure for defining an active region; recessing a gate forming area in the active region defined by the isolation structure; carrying out an ion implantation on a portion of the side wall insulation layer exposed by the recess; removing the portion of the side wall insulation layer subject to the ion implantation to form a moat; and forming a gate over the semiconductor substrate including the moat.

Preferably, the side wall insulation layer includes an oxide layer.

The method may further comprise, after the step of forming the side wall insulation layer and before the step of filling the trench, the step of forming a linear nitride layer over the semiconductor substrate including the side wall insulation layer.

The ion implantation is carried out as an ion implantation for a threshold voltage control.

The ion implantation is carried out using a tilt ion implantation method.

The tilt ion implantation method may be carried out at an implantation angle of 10 to 80°.

The tilt ion implantation method is carried out in a direction of a channel width of the semiconductor device.

Preferably, the ion implantation is carried out using at least one of P-type impurities, Ar, F, and N₂.

Preferably, the ion implantation is carried out at a dose in the range of 1.0×10¹² to 1.0×10¹⁵ ions/cm².

Preferably, the ion implantation is carried out with energy in the range of 10 to 40 keV.

The removal of the portion of the side wall insulation layer subject to the ion implantation is carried out in a cleansing.

The cleansing is carried out suing either HF solution or BOE solution.

Preferably, the moat is formed to a depth of less than half of a channel width.

Preferably, the moat is formed to a depth of 20 to 300 Å.

### BRIEF DESCRIPTION OF THE DRAWINGS

FIG. 1 is a plan view showing a semiconductor device in accordance with an embodiment of the present invention.

FIG. 2 is a cross-sectional view taken along the line II-II′ in FIG. 1 showing the semiconductor device in accordance with an embodiment of the present invention.

FIGS. 3A through 3G are cross-sectional views taken along the line II-II′ in FIG. 1 illustrating steps in a method for manufacturing a semiconductor device in accordance with an embodiment of the present invention.

FIGS. 4A and 4B are graphs illustrating gate characteristics of the semiconductor device in accordance with an embodiment of the present invention.

### DESCRIPTION OF SPECIFIC EMBODIMENTS

Hereinafter, a preferred embodiment of the present invention will be described in detail with reference to the accompanying drawings.

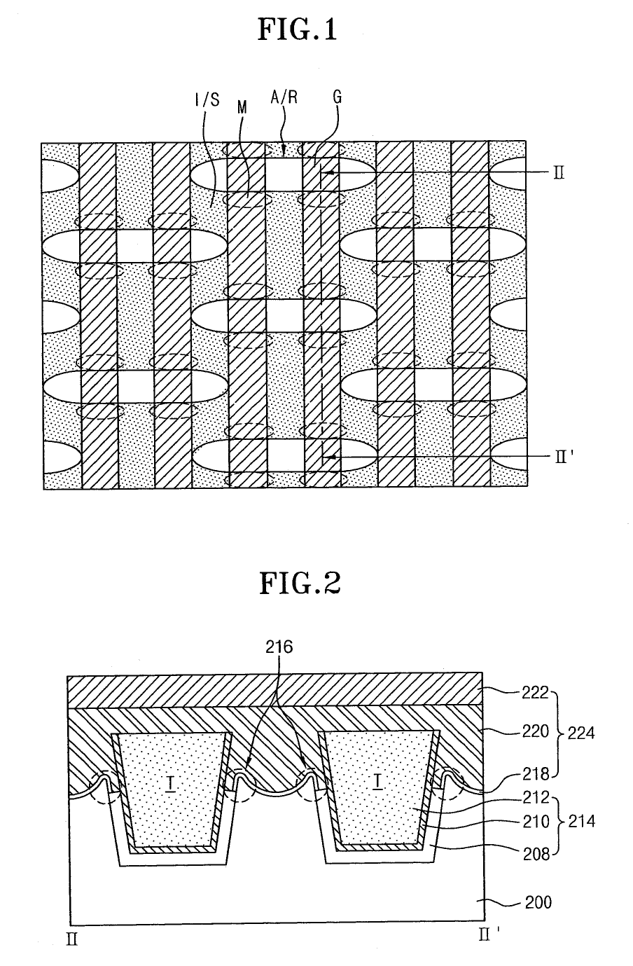

FIGS. 1 and 2 are views showing a semiconductor device in accordance with an embodiment of the present invention. FIG. 1 is a plan view showing an active region, an isolation structure, and a gate line of a semiconductor substrate; and FIG. 2 is a cross-sectional view taken along the line II-II′ in FIG. 1. In FIG. 1, reference symbols A/R and I/S denote respectively an active region and an isolation structure.

Referring to FIG. 2, in a semiconductor substrate 200 provided with an isolation region and an active region and including a gate forming area, an isolation structure 214 for defining the active region is formed, and a gate forming area in the active region is recessed. The isolation structure 214 includes a trench T formed in the isolation region of the semiconductor substrate 200, a side wall insulation layer (preferably a side wall oxide layer 208), formed on a surface of the trench T, a linear nitride layer 210 formed over the side wall oxide layer 208, and an insulation layer 212 formed over the linear nitride layer 210 to fill the trench T.

In the side wall oxide layer 208, an upper end portion of a side wall of the trench T, i.e. a portion adjoining the recessed gate forming area (portion M in FIG. 1), is removed, and a moat 216 is formed at the portion adjacent to the gate forming area in the recessed active region in the direction of a channel width. The moat 216 is formed to a depth of less than half of the channel width, preferably to a depth in the range of 20 to 300 Å.

A gate 224 is formed over the semiconductor substrate 200 including the moat 216. The gate 224 includes a stacked structure of a gate insulation layer 218, a gate conductive layer 220, and a gate hard mask layer 222. The gate insulation layer 218 includes an oxide layer, the gate conductive layer 220 includes a stacked layer structure of a polysilicon layer and a metallic layer, and the gate hard mask layer 222 includes a nitride layer.

As described above, in the semiconductor device in accordance with an embodiment of the present invention, when a portion of the side wall oxide layer 208 of the isolation structure 214 is removed to form the moat 216, the gate can be formed to surround the edge portion of the recessed active region in the direction of the channel width. As such, the gate 224 of the present invention has improved control ability.

Additionally, in the semiconductor device in accordance with an embodiment of the present invention, when the gate 224 is formed to surround the edge portion of the recessed active region in the direction of the channel width, it is possible to improve the threshold voltage characteristics of the gate 224 in the edge portion of the recessed active region. As such, the gate 224 of the present invention has enhanced operation characteristics since its operation current is increased.

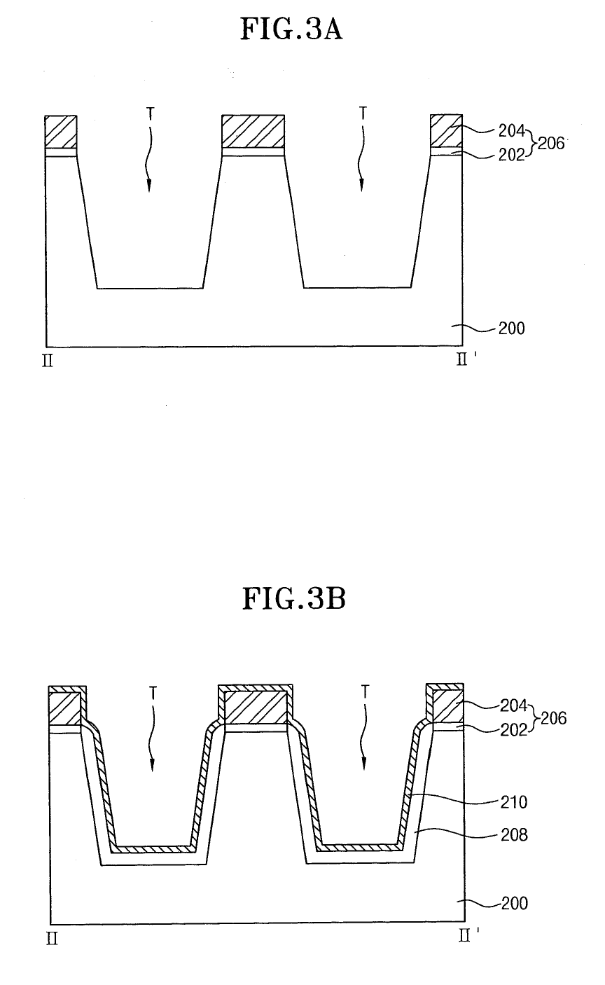

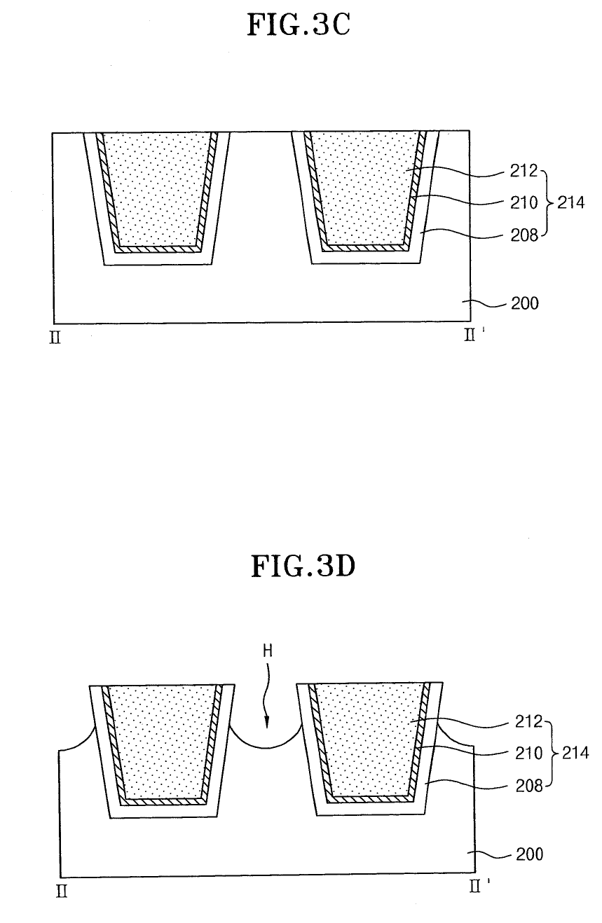

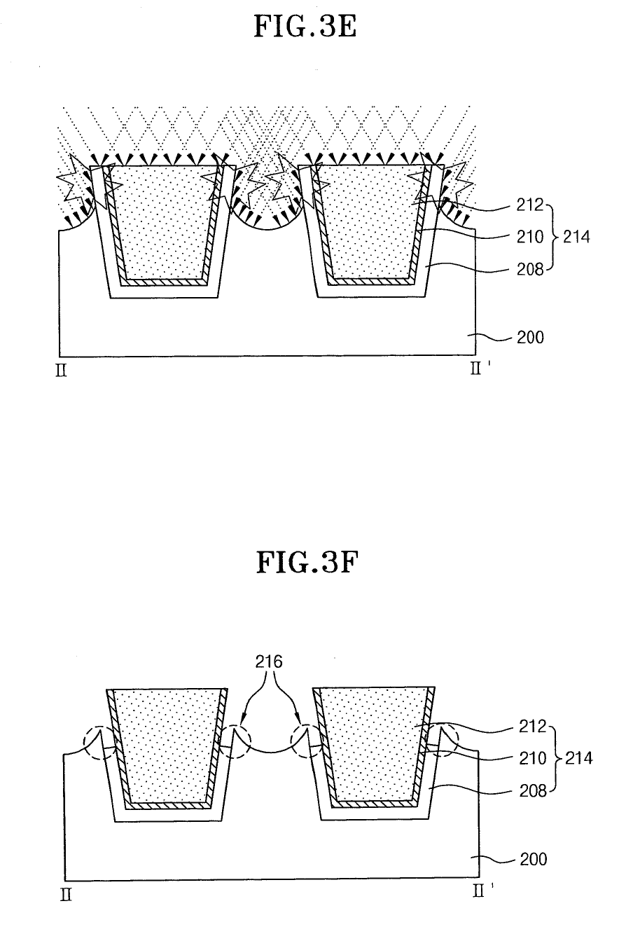

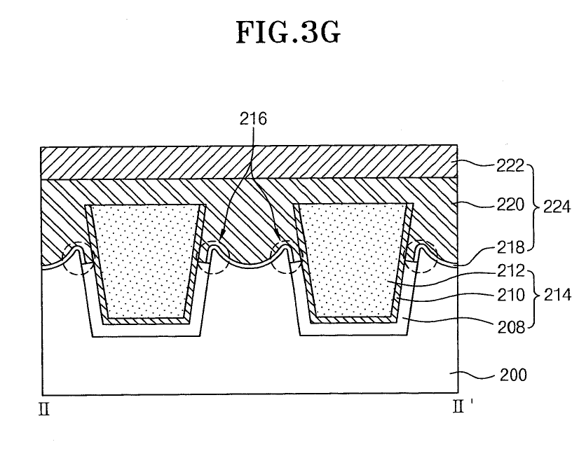

FIGS. 3A through 3G are cross-sectional views taken along a line II-II′ in FIG. 1 and illustrating the steps of a method for manufacturing a semiconductor device in accordance with an embodiment of the present invention.

Referring to FIG. 3A, an isolation mask 206 exposing a predetermined portion of the semiconductor substrate 200 is formed over the semiconductor substrate 200. The isolation mask 206 includes a stacked structure of a pad oxide layer 202 and a pad nitride layer 204. The exposed portion of the semiconductor substrate 200 is etched to form a trench T in the semiconductor substrate 200.

Referring to FIG. 3B, a side wall insulation layer (preferably a side wall oxide layer 208) is formed using a thermal oxidation process over the surface of the trench T. A linear nitride layer 210 is then formed over the isolation mask 206 and the side wall oxide layer 208.

Referring to FIG. 3C, an insulation layer 212 is formed over the linear nitride layer 210 to fill the trench T. The insulation layer 212 is chemical mechanical polished to expose the isolation mask. The isolation mask is then removed to form the isolation structure 214 (which defines the active region) in the trench T.

Referring to FIG. 3D, a recess mask (not shown) exposing the gate forming area in the active region is formed over the semiconductor substrate 200 (which is formed with the isolation structure 214). The exposed gate forming area in the active region is etched to form a groove H.

Referring to FIG. 3E, an ion implantation for threshold voltage control is carried out on the semiconductor substrate 200 (which is formed with the groove H in the gate forming area of the active region). The ion implantation for the threshold voltage control is carried out using P-type impurities at a dose in the range of 1.0×10¹² to 1.0×10¹⁵ ions/cm² with energy in the range of 10 to 40 keV. Also, the ion implantation for the threshold voltage control is carried out in a tilt ion implantation method (for example, at an implantation angle of 10 to 80°) so that impurities can be ion implanted into a portion of the side wall oxide layer which is located at the upper end portion of the side wall of the trench and which is exposed by the recess. The ion implantation for the threshold voltage control (by the tilt ion implantation method) is carried out in the direction of the channel width.

It may be difficult to ensure the desired channel characteristics with the ion implantation for the threshold voltage control using the tilt ion implantation method. In order to compensate for this difficulty, it is possible to carry out an additional ion implantation for the threshold voltage control using a vertical ion implantation method either before or after the ion implantation for the threshold voltage control by the tilt ion implantation method. When the additional ion implantation for the threshold voltage control is carried out, it is possible to use Ar, F, or N₂ when carrying out the ion implantation for the threshold voltage control by the tilt ion implantation method, and it is also possible to use at least one of Ar, F, and N₂ together with the P-type impurities.

When the ion implantation for the threshold voltage control by the tilt ion implantation method is carried out, the portion of the side wall oxide layer 208, which is formed at the upper end portion of the side wall of the trench and exposed by the recess, is subject to ion implantation damage. In the portion of the side wall oxide layer 208 subject to the ion implantation damage, a wet etching speed is increased to a level more than that of the portion which is not subject to the ion implantation damage, and the portion subject to the ion implantation damage is removed in the subsequent cleansing.

Meanwhile, although ion implantation by the tilt ion implantation method is used as the ion implantation for the threshold voltage control and for applying damage to the portion of the side wall 208 (which is formed at the upper end portion of the side wall of the trench T and exposed by the recess), it may also be possible to use an ion implantation such as a channel stop ion implantation, a well ion implantation, and the like.

Referring to FIG. 3F, the recess mask is removed and the semiconductor substrate 200 (into which the ion implantation is carried out) is then cleaned so that impurities and a natural oxide layer occurring on the surface of the semiconductor substrate 200 is removed. The cleansing is carried out using either a HF solution or a buffer oxide etch (BOE) solution. When cleaning the semiconductor substrate 200, the natural oxide layer formed on the surface of the semiconductor substrate 200 is removed, and the exposed portion of the side wall oxide layer 208 (which is subject to the damage during the ion implantation) is selectively removed at the same time. As such, the moat 216 is formed at the side wall of the trench T. The moat 216 is formed to a depth of less than half of the channel width, preferably to a depth in the range of 20 to 300 Å.

Referring to FIG. 3G, a gate insulation layer 218 is formed over the semiconductor substrate 200 (which is formed with the moat 216 at the side wall of the trench the). The gate conductive layer 220 is then formed over the gate insulation layer 218 to fill the groove H, and the gate hard mask layer 222 is formed over the gate conductive layer 220. The gate insulation layer 218 is formed of an oxide layer using a thermal oxidation process, the gate conductive layer 220 is formed in a stacked layer structure of a polysilicon layer and a metallic layer, and the gate hard mask layer 222 is formed of a nitride layer. The gate hard mask layer 222, the gate conductive layer 220, and the gate insulation layer 218 are then etched, thereby forming the gate 224 over the semiconductor substrate 200 including the moat 216.

After that, a series of known follow-up processes are carried out to complete semiconductor device in accordance with an embodiment of the present invention.

As is apparent from the above description, in the present invention, ion implantation damage is applied to a portion of a side wall oxide layer exposed by a groove through ion implantation using a tilt ion implantation method. Wet etching speed in the portion of the side wall oxide layer, which is subject to the ion implantation damage, is increased. It is then possible to form a moat by selectively removing the portion of the side wall oxide layer subject to the ion implantation damage. Therefore, in the present invention, it is possible to form the gate so as to surround the moat, and thus it is possible to improve the control ability of the gate.

Additionally, in the present invention, it is possible to enhance the threshold voltage characteristics of the gate in the portion of the active region adjacent to the moat, i.e. in edges of the recessed portion of the active region, and thus it is possible to prevent a turn-on phenomenon of a channel caused in the edges. Therefore, in the present invention, it is possible to increase the operation current of the gate, and thus improve the operation characteristics.

In addition, in the present invention, it is possible to form the moat only in the gate forming area by selectively removing the portion of the side wall oxide layer subject to the ion implantation damage. Therefore, it is possible to prevent generation of a bridge due to that gate material is remained in the rest portion of the semiconductor substrate other than the gate forming area.

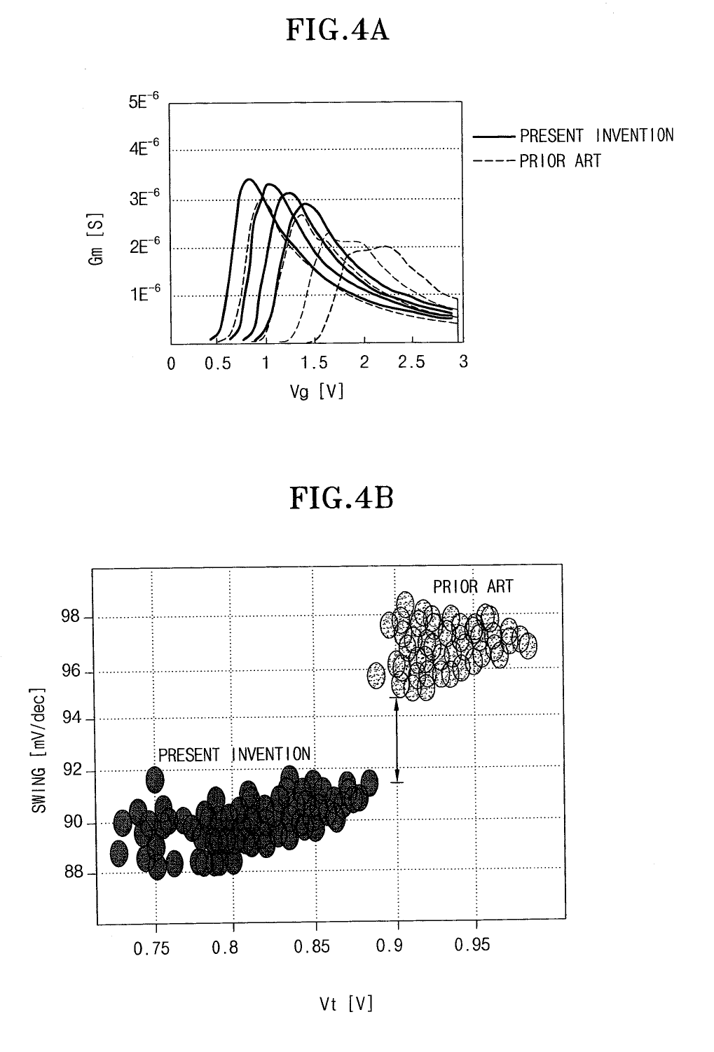

FIGS. 4A and 4B are graphs illustrating the gate characteristics of the semiconductor device in accordance with an embodiment of the present invention. FIG. 4A shows a relationship between a gate voltage Vg and a gate conductance Gm, and FIG. 4B shows a relationship between a threshold voltage Vt of the gate and the swing. The gate conductance in FIG. 4A means a differentiated value of current/voltage, and the swing in FIG. 4B means an inverse number of a gradient of the graph shown in FIG. 4A.

Referring to FIG. 4A, the value of the threshold voltage (Vt) of the gate can be obtained from the graph which shows the relationship between a gate voltage Vg and a gate conductance Gm, and the gradient of the graph is reduced as the threshold voltage characteristic of the gate is lowered. In the present invention, the gradient of the graph is increased; and as such, it can be appreciated that the semiconductor device of the present invention has enhanced threshold voltage characteristics of the gate.

Referring to FIG. 4B, in the present invention, since the gradient of the graph shown in FIG. 4A is increased, it can be appreciated that the swing in the same threshold voltage is reduced in the present invention when compared to the prior art. For example, as shown in FIG. 4B, it can be appreciated that when the threshold voltage of the gate is 0.9 v, the swing in the present invention is reduced by about 4 mv/dec when compared to the prior art.

Therefore, in the present invention, it is possible to reduce the current Ioff during gate off since the swing is reduced. As such, in the present invention, since the threshold voltage in the same Ioff is reduced, the operation current in the same biased state is increased, and thus the operation characteristic of the device can be improved.

Although specific embodiments of the present invention have been described for illustrative purposes, those skilled in the art will appreciate that various modifications, additions and substitutions are possible, without departing from the scope and the spirit of the invention as disclosed in the accompanying claims.

1. A semiconductor device, comprising:
a semiconductor substrate having an isolation region, an active region, and a gate forming area;
an isolation structure formed to define the active region, the isolation structure including a trench formed in the isolation region, a side wall insulation layer formed over the surface of the trench, and an insulation layer formed over the side wall insulation layer to fill the trench;
wherein the gate forming area in the active region is recessed forming a recessed active region;
wherein an upper end portion of the side wall insulation layer adjoining the gate forming area of the recessed active region is removed to form a moat; and
a gate formed to surround an edge portion of the recessed active region in a channel width direction over the semiconductor substrate including the moat.

2. The semiconductor device according to claim 1, wherein the side wall insulation layer includes an oxide layer.

3. The semiconductor device according to claim 1, wherein the isolation structure further includes a linear nitride layer interposed between the side wall insulation layer and the insulation layer.

4. The semiconductor device according to claim 1, wherein the moat has a depth of less than half of a channel width of the semiconductor device.

5. A semiconductor device according to claim 4, wherein the moat has the depth in the range of 20 to 300 Å.

6. A method for manufacturing a semiconductor device, comprising the steps of:
etching a semiconductor substrate to form a trench;
forming a side wall insulation layer over a surface of the trench;
filling the trench with an insulation layer to form an isolation structure for defining an active region;
recessing a gate forming area in the active region;
carrying out an ion implantation on a portion of the side wall insulation layer exposed by the recess;
removing the portion of the side wall insulation layer subject to the ion implantation to form a moat; and
forming a gate over the semiconductor substrate including the moat.

7. The method according to claim 6, wherein the side wall insulation layer includes an oxide layer.

8. The method according to claim 6, further comprising, after the step of forming the side wall insulation layer and before the step of filling the trench, the step of forming a linear nitride layer over the semiconductor substrate including the side wall insulation layer.

9. The method according to claim 6, wherein the ion implantation is carried out as an ion implantation for a threshold voltage control.

10. The method according to claim 6, wherein the ion implantation is carried out using a tilt ion implantation method.

11. The method according to claim 10, wherein the tilt ion implantation method is carried out at an implantation angle of 10 to 80°.

12. The method according to claim 10, wherein the tilt ion implantation method is carried out in a direction of a channel width of the semiconductor device.

13. The method according to claim 6, wherein the ion implantation is carried out using at least one of P-type impurities, Ar, F, and N₂.

14. The method according to claim 6, wherein the ion implantation is carried out at a dose in the range of 1.0×10¹² to 1.0×10¹⁵ ions/cm².

15. The method according to claim 6, wherein the ion implantation is carried out with energy in the range of 10 to 40keV.

16. The method according to claim 6, wherein the removal of the portion of the side wall insulation layer subject to the ion implantation is carried out in a cleansing.

17. The method according to claim 16, wherein the cleansing is carried out suing a HF solution or a BOE solution.

18. The method according to claim 6, wherein the moat is formed to a depth of less than half of a channel width.

19. The method according to claim 18, wherein the moat is formed to a depth in the range of 20 to 300 Å.
